(19) United States
(12) Patent Application Publication
(10) Pub. No.: US 2026/0156769 A1
(43) Pub. Date: Jun. 4, 2026

(54) RACK MOUNT ENCLOSURES

(71) Applicant: Ubiquiti Inc., New York, NY (US)

(72) Inventors: Hsien-Chin CHIANG, New York, NY (US); Yu-Mei SHAN, New York, NY (US); Yun-Ju CHOU, New York, NY (US)

(21) Appl. No.: 19/123,062

(22) PCT Filed: Oct. 19, 2023
(86) PCT No.: PCT/US2023/077347

§ 371 Date: Apr. 21, 2025

Related U.S. Application Data
(60) Provisional application No. 63/417,674, filed on Oct. 19, 2022.

(51) Int. Cl. G04B 19/28; G06F 1/16; G11B 33/12; H05K 7/14

(52) U.S. Cl. CPC H05K 7/1489; G11B 33/02

(57) ABSTRACT

A rack mountable enclosure may be suitable for mounting and enclosing electrical equipment, including electronic servers. The enclosure may include a locking bezel to cover and protect user accessible features from tampering. The enclosure may also include removeable hard-disk drive carriers and latching mechanisms.

### CLAIM OF PRIORITY

This patent application claims priority to U.S. provisional patent application No. 63/417,674, titled “RACK MOUNT ENCLOSURES” and filed on Oct. 19, 2022, herein incorporated by reference in its entirety.

### INCORPORATION BY REFERENCE

All publications and patent applications mentioned in this specification are herein incorporated by reference in their entirety to the same extent as if each individual publication or patent application was specifically and individually indicated to be incorporated by reference.

### FIELD

This disclosure relates generally to rack-mounted equipment, and more specifically to rack-mounted computation and/or server equipment.

### BACKGROUND

Electrical equipment, including but not limited to servers and other computing equipment, may be designed to be installed in standard equipment rack, such as a standard 19-inch rack in accordance with Electronic Industries Association EIA-310. The equipment may have a height that corresponds to a spacing standard, such as a “rack unit”. The equipment may be designed to fit, for example, into a rack slot having a height of one rack unit (“1U”), two rack units (“2U”), or four rack units (“4U”), or the like. Rack-mountable electrical equipment enables the deployment and installation of equipment into any facility that includes a standard equipment rack.

A server may be a particular type of electrical apparatus that includes various compute resources such as one or more power supplies, one or more processors, memory, and one or more hard-disk drives. Rack-mountable servers are often installed into data centers where the facility is shared with various customers. The servers may need to be made accessible for servicing when mounted in an equipment rack. Further, some servers may include user replaceable hard-disk drives. These hard-disk drives may need protection from unauthorized access.

### SUMMARY OF THE DISCLOSURE

Described herein are various apparatuses and systems that may be used in conjunction with a variety of rack-mountable chassis and/or other electrical systems. A rack-mountable chassis (sometimes referred to as a rack-mount enclosure) may be used to enclose various electrical components such as a processor-based server.

In some examples, a rack-mountable chassis may include one or more removable hard-disk drives. The hard-disk drives may be mounted in a hard-disk drive carrier that advantageously includes door that automatically closes when an external user-supplied force is removed.

In some examples, a rack-mountable chassis may include a detachable bezel. The detachable bezel may advantageously attach and lock to the rack-mountable chassis to cover and protect access to some front panel mounted components. The detachable bezel may be unlocked and detached by a key.

In some examples, a rack-mountable chassis may include an assembly to attach, without tools, a module to the front panel. A foldable cable raceway is disclosed that can protect and contain wires or cables.

Any of the apparatuses and/or systems described herein may include a hard-disk drive carrier. In some examples, the hard-disk drive carrier may include a carrier frame configured to receive and affix a hard-disk drive and a door fame coupled to the carrier frame. The door frame may include a door pivotably coupled to the door frame; configured to rotate outward with respect to the door frame, a first spring configured to apply a torsion force to bias the door inward with respect to the door frame, a latch pawl configured to lock the hard-disk drive carrier to a chassis, and a second spring configured to apply a compressive force to bias the latch pawl to protrude beyond the door frame and engage with the chassis, wherein the door is further configured to contact and retract the latch pawl when the door is rotated outward.

In any of the hard-disk drive carriers described herein, the first spring may be a torsion spring disposed about a pivot point, the first spring may include a first arm coupled to the door and a second arm coupled to the door frame. In any of the hard-disk drive carriers, the second spring may be a compression spring comprising a first end in contact with the door frame and a second end in contact with the latch pawl.

In any of the hard-disk drive carriers described herein, the latch pawl may be configured to retract into the door frame when receiving a force from the door. In some examples, the door may further include a tab configured to receive a user applied force to rotate the door outward with respect to the door frame.

In any of the hard-disk drive carriers described herein, the carrier frame may further include a first light pipe configured to transmit light from a first end of the carrier frame to the door. In addition, the door may include a second light pipe configured to transmit light from the first light pipe to an exterior surface of the door.

Any of the apparatuses and/or systems described herein may include a bezel assembly for a rack-mountable chassis. The bezel assembly may include a bezel body, a first latch handle and a second latch handle moveably coupled to the bezel body and configured to extend beyond first and second sides of the bezel body, respectively and engage with a rack-mountable chassis and retract inward from the first and the second sides of the bezel body and disengage from the rack-mountable chassis. The bezel assembly may further include a first compression spring and a second compression spring configured to bias the first latch handle and the second latch handle, respectively, outward to extend beyond the first and the second sides of the bezel body.

Any of the bezel assemblies described herein may include a locking lever configured to lock and maintain an extension of at least one of the first latch handle and the second latch handle beyond the first and second sides of the bezel body when the locking lever is in a first position and allow at least one of the first latch handle and the second latch handle to retract inward from the first and second sides of the bezel body when the locking lever is in a second position, different than the first position.

Any of the bezel assemblies described herein may include a torsion spring coupled to the locking lever and configured to bias the locking lever toward the second position. Furthermore, in any of the bezel assemblies, the bezel body may be locked to the rack-mountable chassis when at least one of the first latch handle and the second latch handle is engaged with the rack-mountable chassis.

In any of the bezel assemblies, the first latch handle and the second latch handle may each be configured to move inward from the first and second sides of the bezel body by a user to disengage the bezel body from the rack-mountable chassis. In any of the bezel assemblies, the bezel body may include a slot to receive a key configured to move the locking lever from the second position to the first position when the key is inserted into the slot. In some examples, the locking lever may be configured to rotate in response to contact from the key.

In any of the bezel assemblies described herein may further include a release button movably coupled to at least one of the first latch handle and the second latch handle, wherein the release button is configured to block user force directed inward to at least one of the first latch handle and the second latch handle when the locking lever is in the second position, and wherein at least one of the first latch handle and the second latch handle is further configured to retract inward when force is directed toward the first latch handle and the second latch handle by the rack-mountable chassis when the locking lever is in the second position.

Generally, any of the bezel assemblies may be configured to prevent user access to hard-disk drive carriers removably coupled to the rack-mountable chassis when engaged to the rack-mountable chassis. Any of the bezel assemblies may include a lock button configured to rotate the locking lever from the second position to the first position when the lock button comes in contact with the rack-mountable chassis. In some examples, the lock button may be configured to extend beyond a surface of the bezel assembly and retract inward with respect to the bezel assembly in response to contacting the rack-mountable chassis.

In any of the bezel assemblies described herein, the locking lever may be further configured to be rotated, by a key, to a third position different from the first and second positions, wherein the first latch handle and the second latch handle are further configured to retract inward from the first and the second sides of the bezel body and disengage from the rack-mountable chassis when the locking lever is in the third position. In some cases, the locking lever may include a surface configured to contact the key and rotate the locking lever in response to pressure from the key. Additionally, or alternatively, at least one of the first latch handle and the second latch handle may include a slot configured to receive the key.

In any of the bezel assemblies described herein, the locking lever may be pivotably coupled to the bezel body. Furthermore, at least one of the first latch handle and the second latch handle may be further configured to include an opening to allow viewing of a display unit mounted to the rack-mountable chassis.

Any of the apparatuses and/or systems described herein may include an enclosure system. The enclosure system may include a rack-mountable chassis including a front panel, wherein the front panel includes at least one rack ear configured to extend beyond the rack-mountable chassis, an equipment rack including rack rails configured to mount electrical equipment within the equipment rack, a hook removably coupled to the rack rail, and a quick release handle coupled to the front panel and configured to engage with the hook to secure the rack-mountable chassis to the rack rails.

In any of the enclosure systems described herein, the quick release handle may include a housing and an actuation lever pivotably coupled to the housing, wherein the actuation lever includes a latch configured to engage the hook removably coupled to the rack rails. As described herein, any of the enclosure systems may include a torsion spring configured to bias the actuation lever to engage the hook. In some examples, the housing may be coupled to the rack ear of the front panel.

In any of the enclosure systems described herein, the front panel may include a cover configured to hold the module against an inner surface of the front panel. The cover may include a hinge, two or more latching arms configured to engage with the front panel and lock the cover against the front panel, and a bracket configured to pivotably couple the cover to the front panel.

Generally, the front panel may include two or more holes configured to engage with the two or more latching arms to lock the cover against the front panel. Additionally or alternatively, the two or more latching arms may be configured to be pressed away from the front panel to release the cover. In some examples, the bracket may be removably coupled to the front panel with screws.

Any of the apparatuses and/or systems described herein may include a for forming a foldable cable raceway. Generally, the blank may include a generally rectangular center panel having first and second sides adjacent to, and on opposing sides of the center panel, a first foldable panel, attached to the first side and configured to form a first side of the cable raceway when folded from the center panel, a second foldable panel, attached to the second side and configured to form a second side of the cable raceway when folded from the center panel, a first top section, attached to the first foldable panel, the first top section comprising an interlocking tab, and a second top section, attached to the second foldable panel, the second foldable panel comprising interlocking fingers configured to receive and restrain the interlocking tab when the first top section is folded toward the second top section thereby forming a cable raceway.

Generally, the blank may include at least one of Mylar, Kapton, and Teflon material. In some examples, the blank may be approximately 0.43 thick. In any of the blanks described herein, the interlocking tab is approximately 13 mm high by 37 mm long and the interlocking fingers are approximately 13 mm high. In any of the blanks described herein the first and second foldable panels are configured to form sides approximately 11 mm tall.

All of the methods and apparatuses described herein, in any combination, are herein contemplated and can be used to achieve the benefits as described herein.

### BRIEF DESCRIPTION OF THE DRAWINGS

A better understanding of the features and advantages of the methods and apparatuses described herein will be obtained by reference to the following detailed description that sets forth illustrative embodiments, and the accompanying drawings of which:

FIG. 1 shows an example rack-mountable chassis.

FIG. 2 shows a detailed view of a rack-mountable chassis.

FIGS. 3A and 3B show a top-down partial view of a hard-disk drive carrier.

FIGS. 4A and 4B show a top-down, partial internal view of a hard-disk drive carrier.

FIGS. 5A and 5B show another view of an example hard-disk drive carrier.

FIG. 6 shows an example rack-mountable chassis assembly.

FIG. 7 shows an example of a bezel system.

FIG. 8 shows an exploded view of a bezel assembly.

FIG. 9 shows an example chassis assembly including a bezel assembly and a rack-mountable chassis.

FIG. 10 shows a partial, top-down internal view of a bezel assembly attached to a rack-mountable chassis.

FIGS. 11A and 11B show a front, internal view of a bezel assembly.

FIG. 12 shows an example rack-mountable chassis system.

FIGS. 13A and 13B show another front, internal view of a bezel assembly.

FIGS. 14A and 14B show an example partial internal view of a bezel assembly.

FIG. 15 shows another example rack-mountable chassis assembly.

FIG. 16 shows another view of the rack-mountable chassis assembly of FIG. 15.

FIG. 17 shows an exploded view of an example bezel assembly.

FIG. 18A shows an example rack-mountable chassis assembly.

FIG. 18B-18E show internal views of the bezel assembly of FIG. 18A.

FIG. 19 shows an exploded view of an example handle.

FIG. 20 shows an example hook assembly for engaging with the handle of FIG. 19.

FIG. 21 shows an example hook attachment.

FIGS. 22A-22D show internal views of an enclosure system.

FIGS. 23A-23D show other views of an enclosure system.

FIGS. 24A and 24B show an example foldable cable raceway system.

FIG. 25 shows various views of a blank for forming a foldable cable raceway.

### DETAILED DESCRIPTION

A rack-mountable chassis and system are disclosed. In particular, a hard-disk drive carrier, detachable and lockable bezels, latches and cable raceways are described.

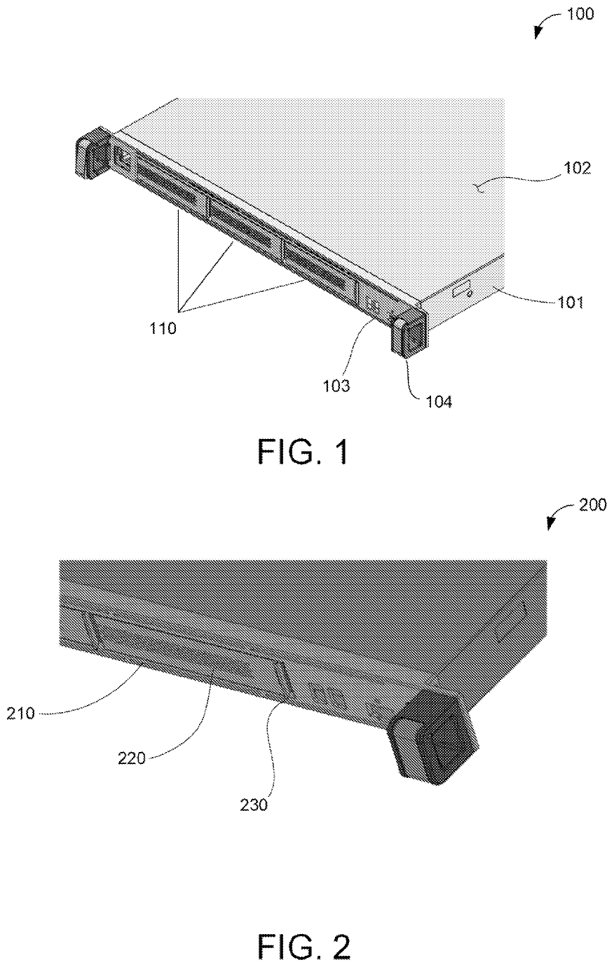

FIG. 1 shows an example rack-mountable chassis 100. The rack-mountable chassis 100 may include one or more sides 101, a cover 102, and a front panel 103. In some examples, the rack-mountable chassis 100 may also include one or more handles 104. The handles 104 may be quick release handles as described below in conjunction with FIGS. 20-23. The rack-mountable chassis 100 may enclose a variety of different electrical equipment and/or components including, for example, computer equipment. The computer equipment may include one or more user accessible hard-disk drives. The hard-disk drives may be mounted on one or more hard-disk drive carriers 110. Example hard-disk drive carriers 110 are described in more detail below in conjunction with FIGS. 2-5.

FIG. 2 shows a detailed view of a rack-mountable chassis 200. The rack-mountable chassis 200 may be an example of the rack-mountable chassis 100 of FIG. 1. The rack-mountable chassis 200 may include a hard-disk drive carrier 210. The hard-disk drive carrier 210 may include a door 220 that further includes a tab 230 that enables a user to engage with and rotate the door 220. In some examples, the user may rotate the door 220 or unlock and disengage the hard-disk drive carrier 210 from the rack-mountable chassis 200. In this manner, the user may remove the hard-disk drive carrier 210 from the rack-mountable chassis 200.

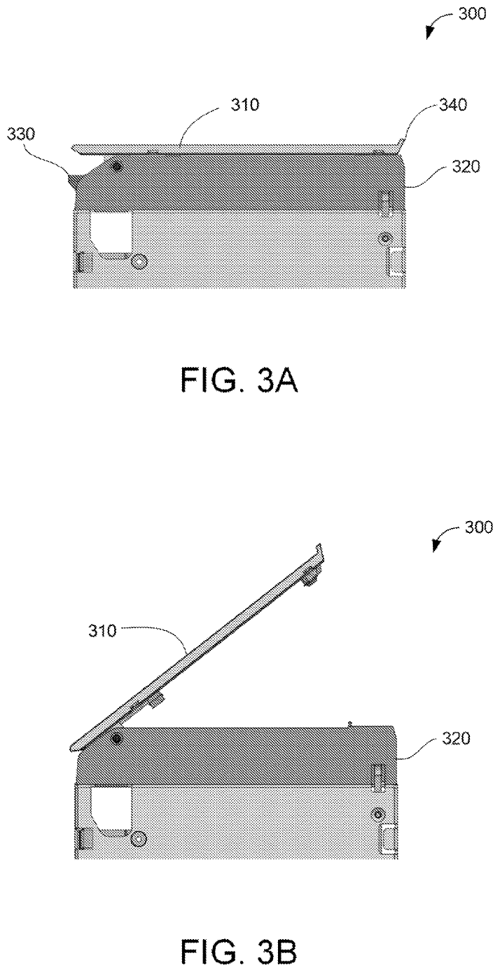

FIG. 3A shows a top-down partial view of a hard-disk drive carrier 300. The hard-disk carrier 300 may be an example of the hard-disk drive carrier 210 of FIG. 2 or any of the hard-disk drive carriers 110 of FIG. 1. The hard-disk drive carrier 300 may include a door 310, a door frame 320, and a latch pawl 330. The door 310 may be directly or indirectly coupled to the latch pawl 330. In some examples, the door 310 may be pivotably coupled to the door frame 320. Rotation of the door 310 about a pivot point anchored to the door frame 320 may cause the door 310 to contact the latch pawl 330 and retract the latch pawl 330 into the door frame 320. The latch pawl 330 may protrude from the door frame 320 and cause the hard-disk drive carrier 300 to be latched or locked within a chassis, such as the rack-mountable chassis 200 of FIG. 2 or the rack-mountable chassis 100 of FIG. 1. In some examples, the door 310 may include a tab 340 that enables a user to grasp and rotate the door 310 with respect to the door frame. Although not shown, the hard-disk drive carrier 300 may include a carrier frame that can receive and affix (mount) a hard-disk drive.

FIG. 3B shows another top-down partial view the hard-disk drive carrier 300. As shown, the door 310 may be rotated about a pivot point with respect to the door frame 320. Rotation of the door 310 may cause the latch pawl (not shown) to be retracted or withdrawn within the door frame 320.

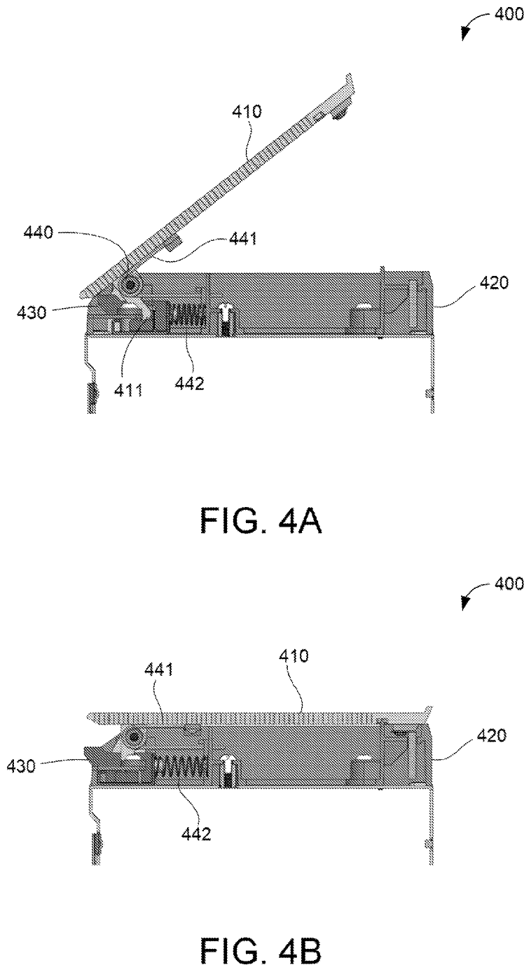

FIG. 4A shows a top-down, partial internal view of a hard-disk drive carrier 400. FIG. 4A may be show example internal components of the hard-disk drive carrier 300 of FIG. 3. The hard-disk drive carrier 400 may include a door 410, a door frame 420 and a latch pawl 430. In addition, the hard-disk drive carrier 400 may include a pivot 440, a first spring 441, and a second spring 442.

The door 410 may be pivotably coupled to the door frame 420 through the pivot 440. The first spring 441 may include a first arm coupled to the door 410 and a second arm coupled to the door frame 420. The first spring 441 may bias the door 410 closed. For example, the door 410 may be rotated outward (with respect to the door frame 420) by a user. The first spring 441 may exert a torsion force on the door 410 to return the door 410 toward the door frame 420 (closed). In some examples, the first spring 441 may be a torsion spring configured to exert a twisting force with respect to the door 410 and the door frame 420. The first spring 441 may be disposed around the pivot 440. In this manner, the first spring 441 may advantageously close the door 410 when an external user-supplied force is removed.

The second spring 442 may be coupled to the latch pawl 430. In some examples, the second spring 442 may exert a compressive force to bias the latch pawl 430 outward from the door frame 420. The door 410 may include a lever 411 that may contact and move the latch pawl 430 inward as the door 410 is rotated outward from the door frame 420. In this manner, rotation of the door 410 may cause the latch pawl 430 to be withdrawn (retracted) into the door frame 420. In some examples, the second spring 442 may be a compression spring. In some cases, as the second spring 442 exerts pressure on the latch pawl 430 outward, the second spring 442 may also exert a force to rotate the door 410 inward toward a center of the door frame 420.

FIG. 4B shows another top-down, partial internal view of the hard-disk drive carrier 400. As shown, the door 410 may be rotated “closed” (inward) resting against the door frame 420. In some examples, the first spring 441 may apply a force to rotate the door 410 inward with respect to the door frame 420.

The second spring 442 may bias and/or force the latch pawl 430 outward from the door frame 420. The latch pawl 430 may engage with a feature within the chassis (not shown) to lock the hard-disk drive carrier 400 in place with respect to the chassis.

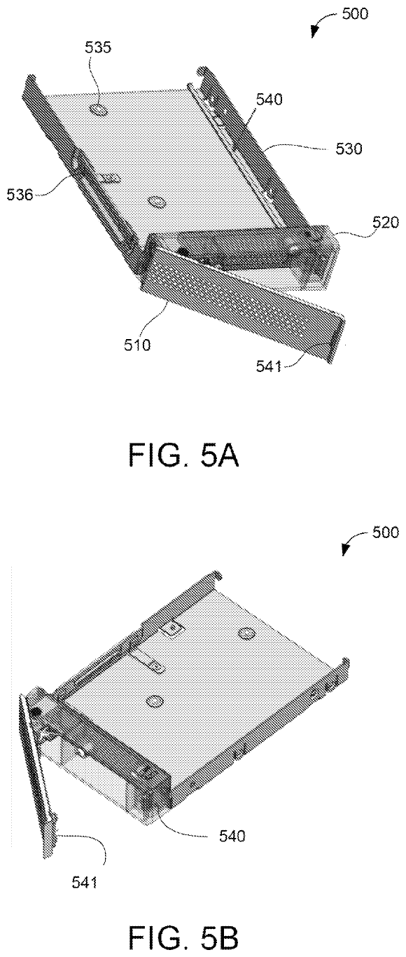

FIG. 5A shows another view of an example hard-disk drive carrier 500. The hard-disk drive carrier 500 may be another example of the hard-disk drive carrier 210 of FIG. 2. The hard-disk drive carrier 500 may include a door 510, a door frame 520, and a carrier frame 530. The carrier frame 530 may be configured to receive and affix a hard-disk drive. For example, the carrier frame 530 may include holes 535 and/or brackets 536 for attaching any feasible hard-disk drive.

In some examples, a rack-mountable chassis may include a light emitting diode (LED) that can provide information regarding hard-disk drive activity or status. The LED may be mounted on a printed circuit board (PCB) that may be located internally (e.g., not readily visible from outside the rack-mountable chassis). The hard-disk drive carrier 500 may include one or more light pipes to transmit light from the LED mounted on an internal PCB to a surface visible outside of the rack-mountable chassis.

For example, the hard-disk drive carrier 500 may include a first light pipe 540 and a second light pipe 541. The first light pipe 540 and the second light pipe 541 may be an acrylic or polycarbonate material that may allow near total internal refection of light. In some examples, the first light pipe 540 may transmit light from an LED mounted on the PCB toward the door 510. The second light pipe 541 may be mounted within the door 510 and positioned to transmit light from the first light pipe 540 to an outer or exterior surface of the door 510, particularly when the door 510 is closed (rotated inward with respect to the door frame 520). In some examples, the second light pipe 541 may contact the first light pipe 540 when the door 510 is rotated inward towards the door frame 520.

FIG. 5B shows another view of the hard-disk drive carrier 500. As shown, the first light pipe 540 may include a surface to align and/or contact with the second light pipe 541 mounted on or within the door 510.

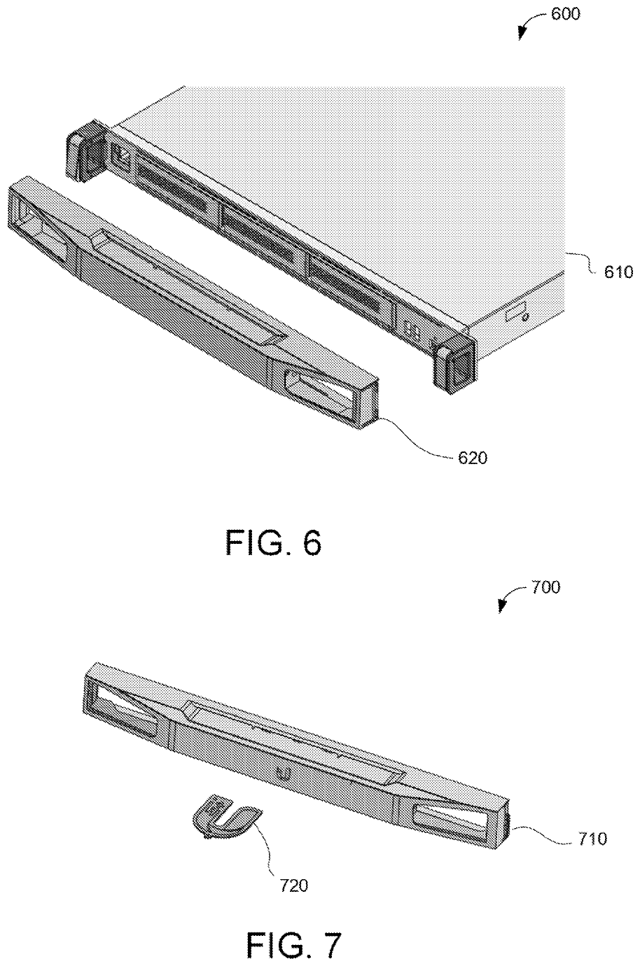

FIG. 6 shows an example rack-mountable chassis assembly 600. The rack-mountable chassis assembly 600 may include a rack-mountable chassis 610 and a bezel assembly 620. As described herein, in some examples the rack-mountable chassis 610 may include features that should be hidden or protected from access by unauthorized personnel, such as hard-disk drive carriers, power buttons, or the like. The bezel assembly 620 may be used to secure or protect the front of the rack-mountable chassis 610. In some examples, the bezel assembly 620 may be secured with a key or other similar feature to the front of the rack-mountable chassis 610. Example bezel assemblies are described in more detail below in conjunction with FIGS. 7-19.

FIG. 7 shows an example of a bezel system 700. The bezel system 700 may include a bezel assembly 710 and a key 720. The bezel assembly 710 may be removably coupled to a rack-mountable chassis and include one or more user operable latch handles that may enable a user to unlatch and remove the bezel assembly 710 from the rack-mountable chassis. In some examples, the key 720 (or lack thereof) may be used restrict or prevent any movement of the user operable latch handles, thereby effectively locking the detachable bezel 710 to the rack-mountable chassis.

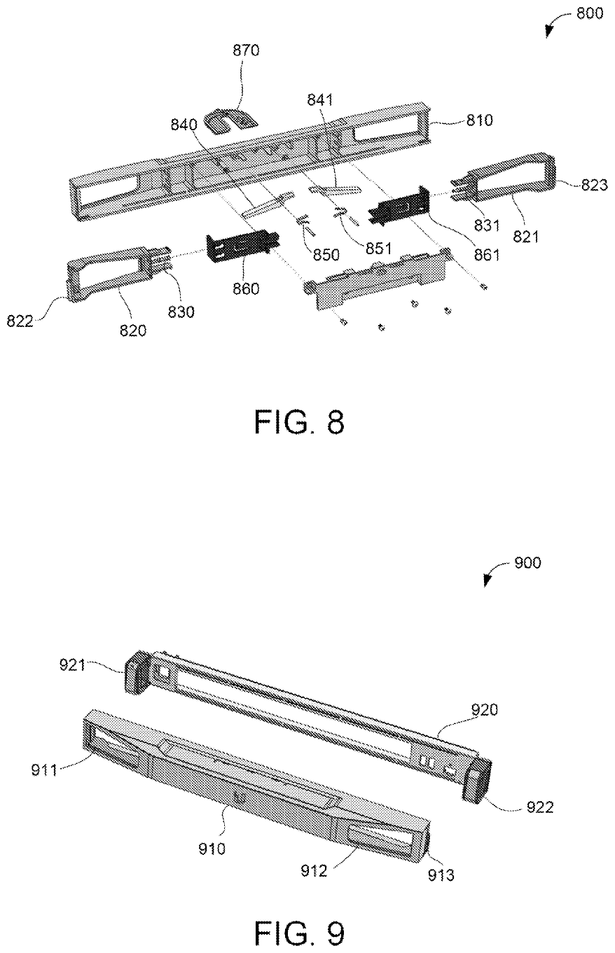

FIG. 8 shows an exploded view of a bezel assembly 800. The bezel assembly 800 may include a bezel body 810, a first latch handle 820, a second latch handle 821, a first compression spring 830, a second compression spring 831, a first locking lever 840, a second locking lever 841, a first torsion spring 850, a second torsion spring 851, a first release button 860, and a second release button 861. In some examples, the bezel assembly 800 may include additional components not listed here such as screws, covers, plates or the like. Some other example bezel assemblies may include additional or fewer components.

The first and second latch handles 820 and 821 may extend outward beyond sides or edges of the bezel body 810. For example, the first compression spring 830 may bias or force the first latch handle 820 to extend outward from the bezel body 810 and the second compression spring 831 may bias or force the second latch handle 821 to extend outward from the bezel body 810. Features (prongs 822 and 823) of the first and second latch handles 820 and 821, respectively, that extend beyond the bezel body 810 may engage or lock the bezel body 810 to a rack-mountable chassis (not shown).

The first release button 860 may be movably coupled to the first latch handle 820 and the second release button 861 may be movably coupled to the second latch handle 821. In some examples, the first and second release buttons 860 and 861 may allow the first and second latch handles 820 and 821 to retract inward when a force is exerted onto the prongs 822 and 823 of the first and second latch handles 820 and 821. In this manner, the first and second release buttons 860 may always allow the bezel assembly 800 to be installed or attached to a rack-mountable chassis.

The first and second release buttons 860 and 861 may also prevent retraction of the first and second latch handles 820 and 821 by a user trying to push inward on the first and second latch handles 820 and 821, particularly when a key 870 is not inserted into the bezel body 810. In other words, the first and second release buttons 860 and 861 may block a pressure or force from a user directed toward the first and second latch handles 820 and 821. For example, the first and second locking levers 840 and 841 may be biased by the first and second torsion springs 850 and 851 into a position that prevents the first and second release buttons 860 and 861 from moving and thereby locking and maintaining an extension (or position) of the first and second latch handles 820 and 821. In some examples, when the first and second release buttons 860 and 861 are prevented from moving, they can block any user provided force from reaching and/or actuating the first and second latch handles 820 and 821. When the key 870 is inserted into the bezel body 810, then the first and second locking levers 840 and 841 may be moved (by contact from the key 870, for example) into a position that allows the first and second release buttons 860 and 861 to move and thereby allowing the first and second latch handles 820 and 821 to move and retract inward away from sides of the bezel body 810.

FIG. 9 shows an example chassis assembly 900 including a bezel assembly 910 and a rack-mountable chassis 920. The rack-mountable chassis 920 may include a first handle 921 and a second handle 922. The rack-mountable chassis 920 may also include sides, cover, etc. not shown in this view.

The bezel assembly 910, which may be an example of the bezel assembly 800 of FIG. 8, may include a first latch handle 911 and a second latch handle 912. Each of the first latch handle 911 and the second latch handle 912 may include prongs (such as prong 913) that may engage with a handle of the rack-mountable chassis 920.

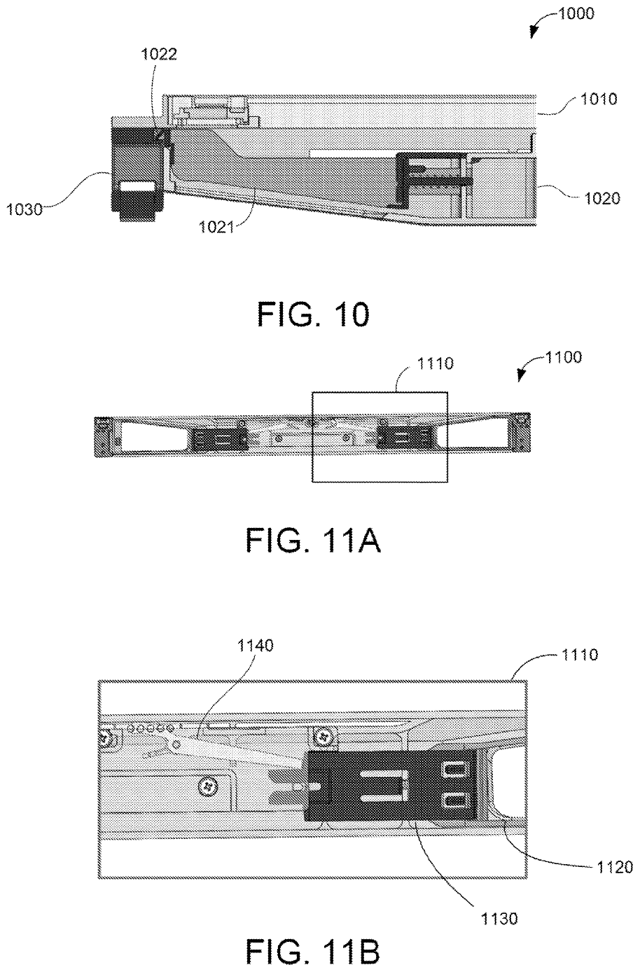

FIG. 10 shows a partial, top-down internal view 1000 of a bezel assembly attached to a rack-mountable chassis. As shown, a bezel assembly 1020 may be attached to a rack-mountable chassis 1010. The rack-mountable chassis 1010 may include a handle 1030. The bezel assembly 1020 may include a latch handle 1021. The latch handle 1021 may include a prong 1022 that can engage with the handle 1030 to hold the bezel assembly 1020 onto the rack-mountable chassis 1010.

FIG. 11A shows a front, internal view of a bezel assembly 1100. The bezel assembly 1100 may be an example of the bezel assembly 800 of FIG. 8. A region 1110 of the bezel assembly 1100 is shown enlarged in FIG. 11B.

FIG. 11B shows the region 1110 of the bezel assembly 1100. The region 1110 may include a latch handle 1120, a release button 1130, and a locking lever 1140. When a key is not inserted into the bezel assembly 1100, the locking lever 1140 may be biased by a torsion spring (not shown) in a manner that interferes or prohibits motion of the release button 1130. In this position, the locking lever 1140 may block force from a user trying to move the latch handle 1120 inward. Therefore, when motion of the release button 1130 is restricted, the user cannot move the latch handle 1120 inwardly to retract a prong from a handle (prong and handle not shown).

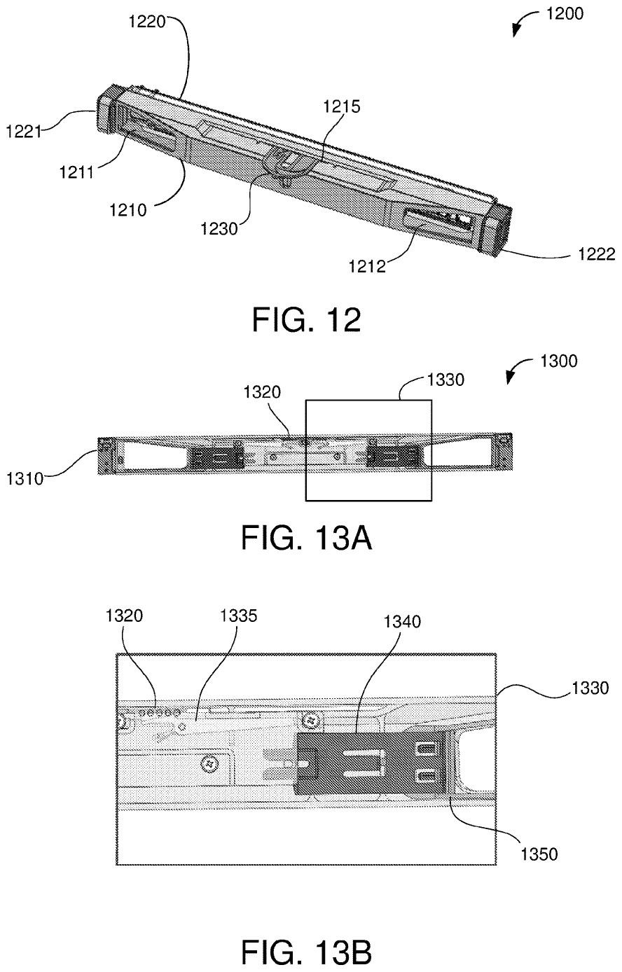

FIG. 12 shows an example rack-mountable chassis system 1200. The rack-mountable chassis system 1200 may include a bezel assembly 1210 and a rack-mountable chassis 1220. The bezel assembly 1210 may be an example of the bezel assembly 800 of FIG. 8 and include a first latch handle 1211 and a second latch handle 1212. The rack-mountable chassis 1220 may include a first handle 1221 and a second handle 1222. A key 1230 may be inserted into a slot 1215 of the bezel assembly 1210 to allow a user to retract the first and second latch handles 1211 and 1212 inwardly and un-attach the bezel assembly 1210 from the rack-mountable chassis 1220.

FIG. 13A shows another front, internal view of a bezel assembly 1300. A bezel assembly 1300 may be an example of the bezel assembly 800 of FIG. 8. A key 1320 may be inserted into a slot in the bezel assembly 1310. A region 1330 of the bezel assembly 1300 is shown enlarged in FIG. 13B.

FIG. 13B shows the region 1330 of FIG. 13B. As shown, the key 1320 may be inserted into a slot and may cause a locking lever 1335 to move, rotate, and no longer limit motion of a release button 1340. Thus, the user may move both the release button 1340 and the handle latch 1350 to release the bezel assembly 1310 from the rack-mountable chassis.

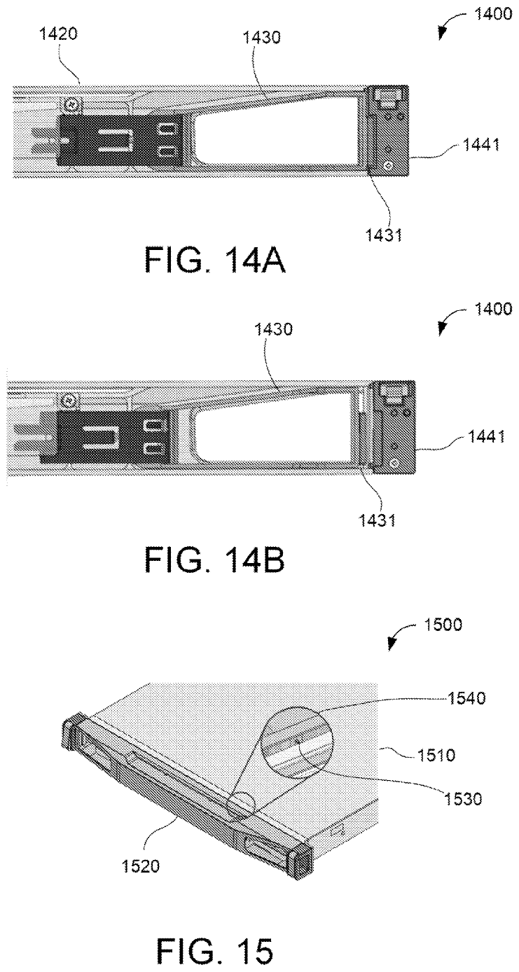

FIG. 14A shows an example partial internal view of a bezel assembly 1400. The bezel assembly 1400 may be an example of the bezel assembly 800 of FIG. 8. The bezel assembly 1400 may include a bezel body 1420, a latch handle 1430 with a prong 1431 that extends beyond sides of the bezel body 1420. The prong 1431 can engage with a handle 1441 of a rack-mountable chassis.

FIG. 14B shows another example partial internal view of the bezel assembly 1400. As shown, the latch handle 1430 may be moved inwardly causing the prong 1431 to disengage from the handle 1441 thereby allowing removal or unattachment of the bezel assembly 1400 from the rack-mountable chassis.

FIG. 15 shows another example rack-mountable chassis assembly 1500. The rack-mountable chassis assembly 1500 may include a rack-mountable chassis 1510 and a bezel assembly 1520. The bezel assembly 1520 may include a lock button 1530, shown in inset 1540. The lock button 1530 may detect when the bezel assembly 1520 is attached to the rack-mountable chassis 1510. Detection of whether the bezel assembly 1520 is attached to the rack-mountable chassis 1510 may enable the bezel assembly 1520 to be locked to the rack mountable chassis 1510.

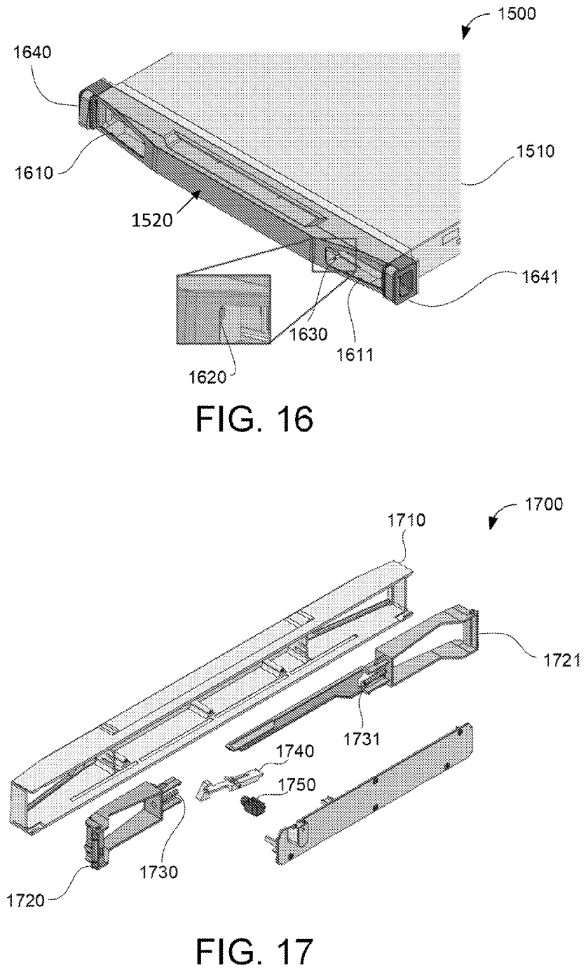

FIG. 16 shows another view of the rack-mountable chassis assembly 1500 of FIG. 15. The rack-mountable chassis 1510 may include a first handle 1640 and a second handle 1641. The bezel assembly 1520 may include a first latch handle 1610, a second latch handle 1611, and a slot 1620 which can accept a key 1630. When the key 1630 is fully inserted into the slot 1620, the first and second latch handles 1610 and 1611 may be moved inward withdrawing prongs (not shown) from the first and second handles 1640 and 1641. When the prongs are retracted and moved inward, the bezel assembly 1520 may be detached from the rack-mountable chassis 1510.

FIG. 17 shows an exploded view of an example bezel assembly 1700. The bezel assembly 1700 may include a bezel body 1710, a first latch handle 1720, a second latch handle 1721, a first compression spring 1730, a second compression spring 1731, a locking lever 1740 and a lock button 1750. The first and second latch handles 1720 and 1721 may function in a similar manner as described above with respect to the bezel assembly 800 of FIG. 8. For example, the first compression spring 1730 may exert a force on the first latch handle 1720 to bias and push the first latch handle 1720 outward with respect to the bezel assembly 1700. The second compression spring 1731 may exert a force on the second latch handle 1721 to bias and push the second latch handle 1721 outward with respect to the bezel assembly 1700. The locking lever 1740 may rotate and, in some positions, limit or restrict the movement of the first and second latch handles 1720 and 1721 thereby locking the bezel assembly 1700 onto the rack-mountable chassis.

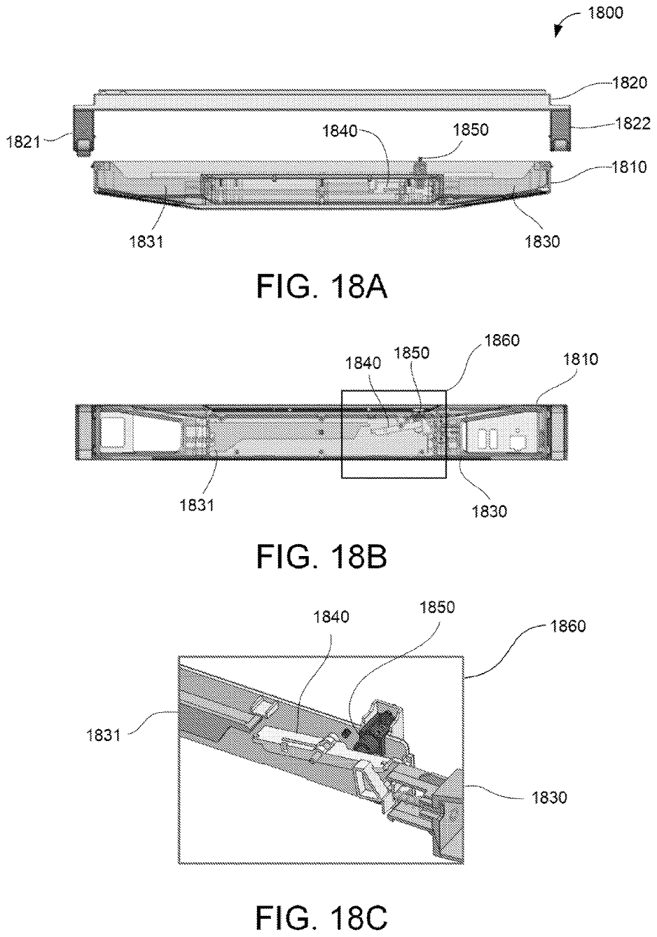

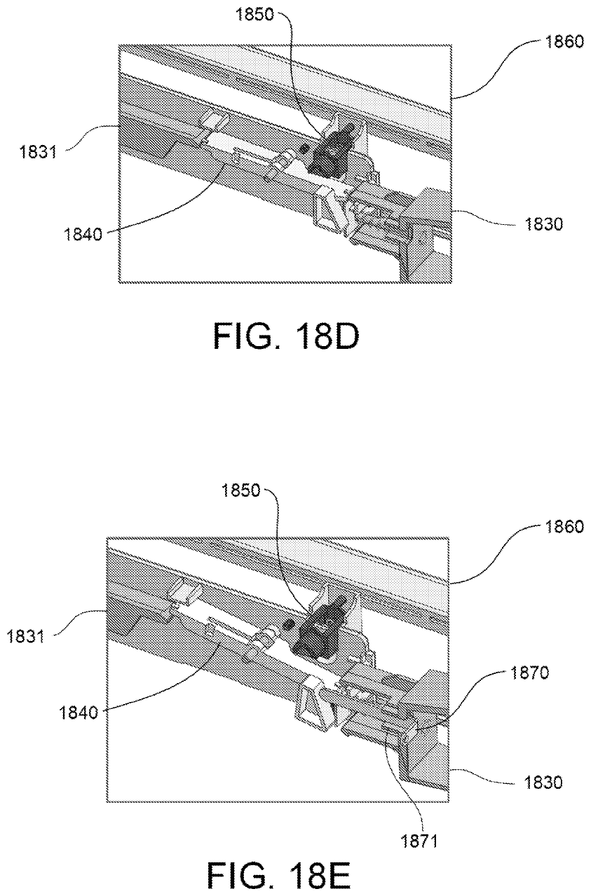

FIG. 18A shows an example rack-mountable chassis assembly 1800 including a bezel assembly 1810 and a rack-mountable chassis 1820. The rack-mountable chassis 1820 may include a first handle 1821 and a second handle 1822. The bezel assembly 1810 may include a first latch handle 1830, a second latch handle 1831, a locking lever 1840, and lock button 1850.

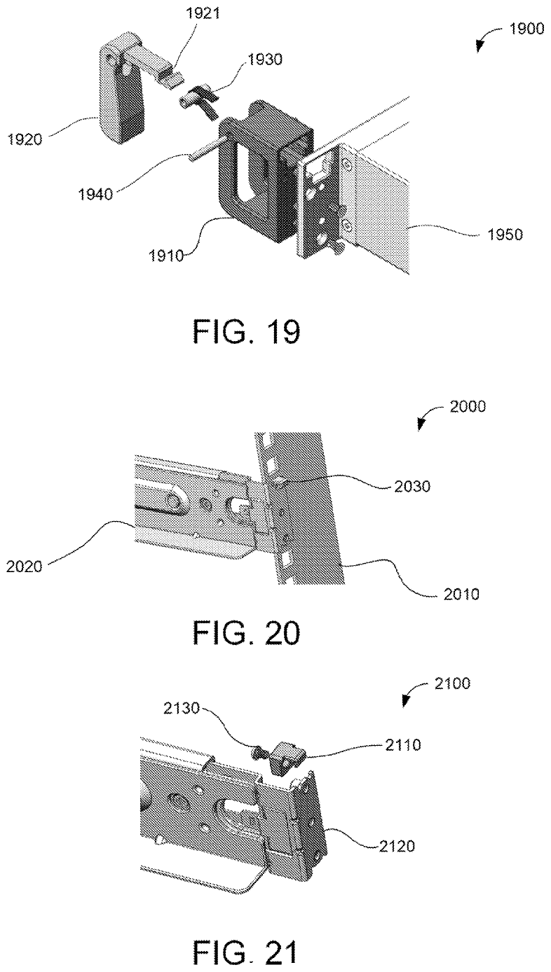

FIG. 18B shows an internal view of the bezel assembly 1810 of FIG. 18A. The bezel assembly 1810 may include the first latch handle 1830, the second handle 1831, the locking lever 1840 and the lock button 1850. Also shown is region 1860. The locking lever 1840, located within region 1860, may control, at least in part, a locking function of the first latch handle 1830 and the second latch handle 1831. Operation of the locking lever 1840 is described in more detail below with respect to FIGS. 19-21.

FIG. 18C shows the region 1860 of FIG. 18B with the locking lever 1840 in a first position. The first latch handle 1830, the second latch handle 1831, the locking lever 1840, and the lock button 1850 are also shown within the region 1860. In addition, a torsion spring (not shown) may be coupled to the locking lever 1840. The torsion spring may bias the locking lever 1840 to a first position as shown. In this position, the bezel assembly 1810 may not be attached to the rack-mountable chassis. Therefore, the lock button 1850 may be at least partially extending beyond a side of the bezel assembly 1810.

When the lock button 1850 is extending at least partially beyond the bezel assembly 1810, then the locking lever 1840 may rotate to a first position biased, at least in part, by the torsion spring. In the first position, the first latch handle 1830 and the second latch handle 1831 may be free to be moved inward, with respect to the bezel assembly 1810. In this manner, a user may attach the bezel assembly 1810 to the rack-mountable chassis. For example, when the user pushes the bezel assembly 1810 toward a front panel of the of the rack-mountable chassis, prongs of the first and second latch handles 1830 and 1831 may contact handles of the rack-mountable chassis and be pushed inward from the contact.

FIG. 18D shows the region 1860 with the locking lever 1840 in a second position. The lock button 1850 may come in contact with the rack-mountable chassis and become moved (pushed) inward. As the lock button 1850 pushes inward, the lock button 1850 may cause the locking lever 1840 to rotate to the second position illustrated in FIG. 19B. In the second position, the locking lever 1840 may inhibit or prevent movement of the first latch handle 1830 and the second latch handle 1831 such that a user cannot push the first and second latch handles 1830 and 1831 inward to allow the bezel assembly 1810 to be removed from the rack-mountable chassis.

FIG. 18E shows the region 1860 with the locking lever 1840 in a third position. As shown, a key 1870 may be inserted into a slot 1871 and rotate the locking lever 1840 into a third position. In the third position, the locking lever 1840 has moved to a position that allows the first latch handle 1830 and the second latch handle 1831 to move inward and allow the bezel assembly 1810 to be removed from the rack-mountable chassis.

FIG. 19 shows an exploded view of an example handle 1900. The handle 1900 may include a housing 1910, an actuation lever 1920, a torsion spring 1930 and a pivot pin 1940. In some examples, the handle 1900 may be a quick release handle that can detachably couple or attach a rack-mountable chassis to an equipment rack. For example, the handle 1900 may lock a rack-mountable chassis mounted on rack rails to an equipment rack. Generally, rack rails may be used to mount or attach a variety of equipment, particularly electrical equipment to the equipment rack. Although shown here as one rack unit tall (e.g., 1U), in other examples the handle 1900 may be scaled to any feasible size and be used with any size of rack-mountable chassis.

The actuation lever 1920 may be pivotably coupled to the housing 1910 via the pivot pin 1940. The actuation lever 1920 may include a latch 1921. The latch 1921 may engage with a hook that is mounted to the equipment rack (not shown). The torsion spring 1930 may bias a position of the actuation lever 1920. As shown, the handle 1900 may be attached with screws to rack ears of a rack-mountable chassis 1950. In other examples, the handle 1900 may be attached to the rack-mountable chassis 1950 with any other feasible means.

FIG. 20 shows an example hook assembly 2000 for engaging with the handle 1900 of FIG. 19. The hook assembly 2000 may include an equipment rack 2010, a rack rail 2020, and a hook 2030. The hook 2030 may be coupled directly or indirectly to the equipment rack 2010. Although only one side of the equipment rack 2010 is shown, the hook assembly 2000 may be replicated on either or both sides of the equipment rack 2010.

The rack rail 2020 may be used to slidably couple a rack-mountable chassis to the equipment rack 2010. Thus, in some examples the rack rail 2020 may be attached to the equipment rack 2010. The hook 2030 may protrude or extend beyond a surface of the equipment rack 2010. In this manner, the hook 2030 may engage with a latch of the handle 1900 of FIG. 19.

FIG. 21 shows an example hook attachment 2100. As shown, a hook 2110 (which may be an example of the hook 2030 of FIG. 20) may be coupled to a rack rail 2120 (which may be an example of the rack rail 2020 of FIG. 20). In some examples, the hook 2110 may be attached to the rack rail 2120 with a screw 2130.

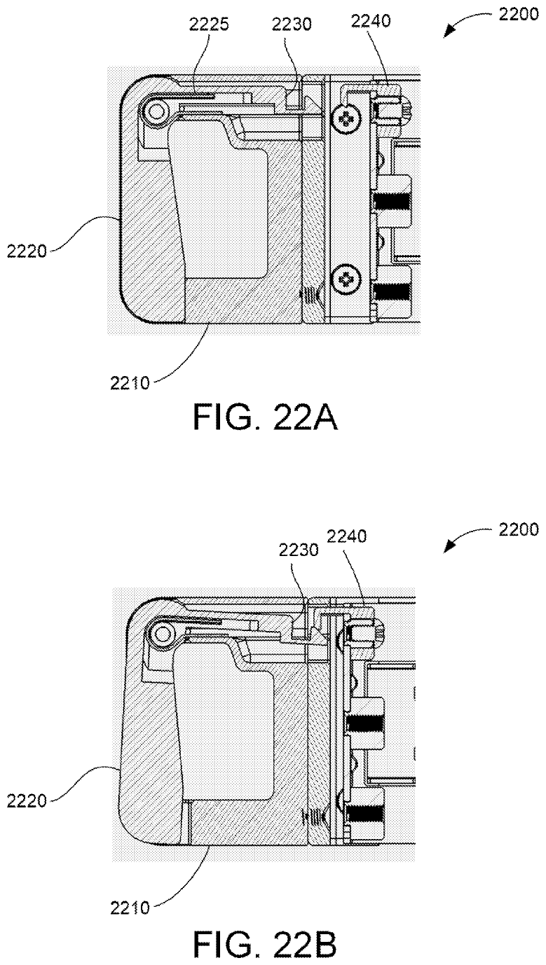

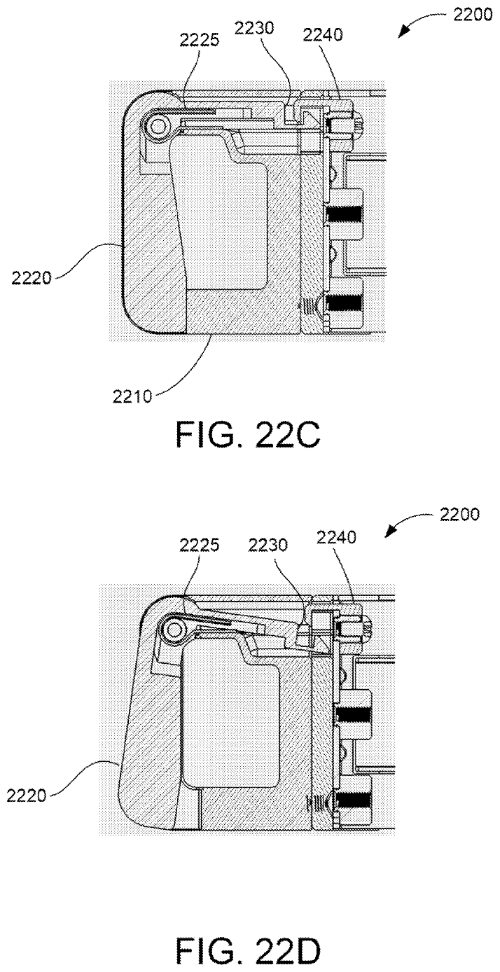

FIG. 22A shows a first internal view of an enclosure system 2200. The enclosure system 2200 may include a handle 2210 and a hook 2240. The handle 2210 may include a torsion spring 2225 and an actuation lever 2220 that in turn may include a latch 2230.

As shown, the latch 2230 may have not yet engaged the hook 2240. For example, a user may be sliding a rack-mountable chassis forward, with respect to an equipment rack, toward the hook 2240. The torsion spring 2225 may bias the actuation lever 2220 into a first position as shown.

FIG. 22B shows a second internal view of the enclosure system 2200. As the handle 2210 slides toward the hook 2240, the latch 2230 may contact the hook 2240. The hook 2240 may cause the actuation lever 2220 to pivot. The torsion spring 2225 may continue to bias the actuation lever 2220, in this case allowing the actuation lever 2220 to be deflected and pivot due to contact with the hook 2240.

FIG. 22C shows a third internal view of the enclosure system 2200. In this view, the handle 2210 has been moved toward the hook 2240 such that the latch 2230 can fully engage the hook 2240. The torsion spring 2225 may continue to bias the actuation lever 2220 so that the latch 2230 may maintain engagement with the hook 2240. In this manner, the rack-mountable chassis may be locked to the equipment rack.

FIG. 22D shows a fourth internal view of the enclosure system 2200. In this view, the actuation lever 2220 may be pivoted by the user so that the latch 2230 can disengage from the hook 2240. For example, the user may overcome the bias force provided by the torsion spring 2225. When the latch 2230 is disengaged from the hook 2240, the user may move the rack-mountable chassis away from the equipment rack.

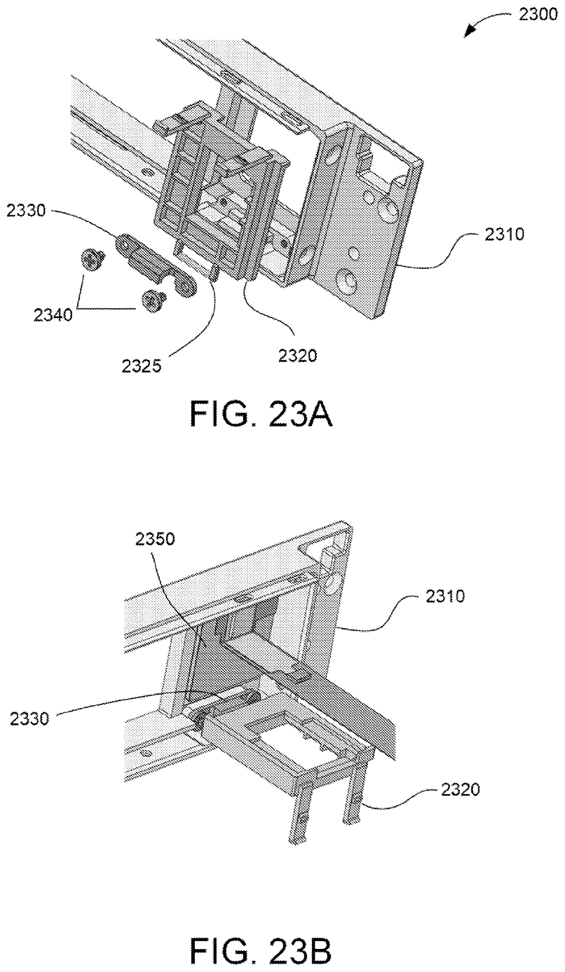

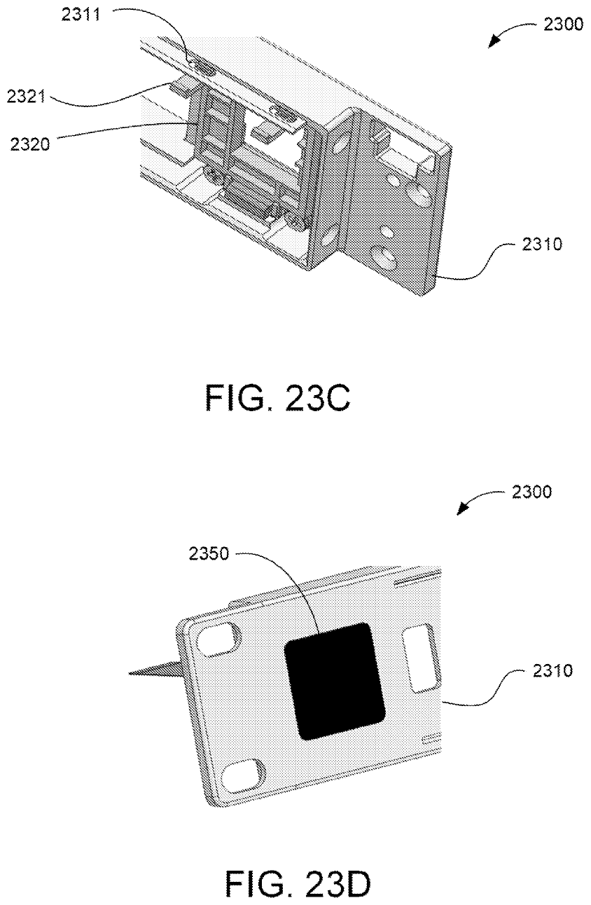

FIG. 23A shows another view of an enclosure system 2300. The enclosure system 2300 may include a front panel 2310, a cover 2320, a bracket 2330 and screws 2340. In some examples, the front panel 2310 may be the front panel of any feasible rack-mountable chassis as described herein.

The cover 2320 may be used to affix, install, or lock a component, module, display unit, or the like, in place with respect to an inner surface of the front panel 2310. The cover 2320 may include a hinge 2325 that allows the cover 2320 to be pivotably coupled to the front panel 2310. In some examples, the bracket 2330 may capture and hold the hinge 2325 with respect to the front panel 2310. The screws 2340 may be used to hold the bracket 2330 to the front panel 2310.

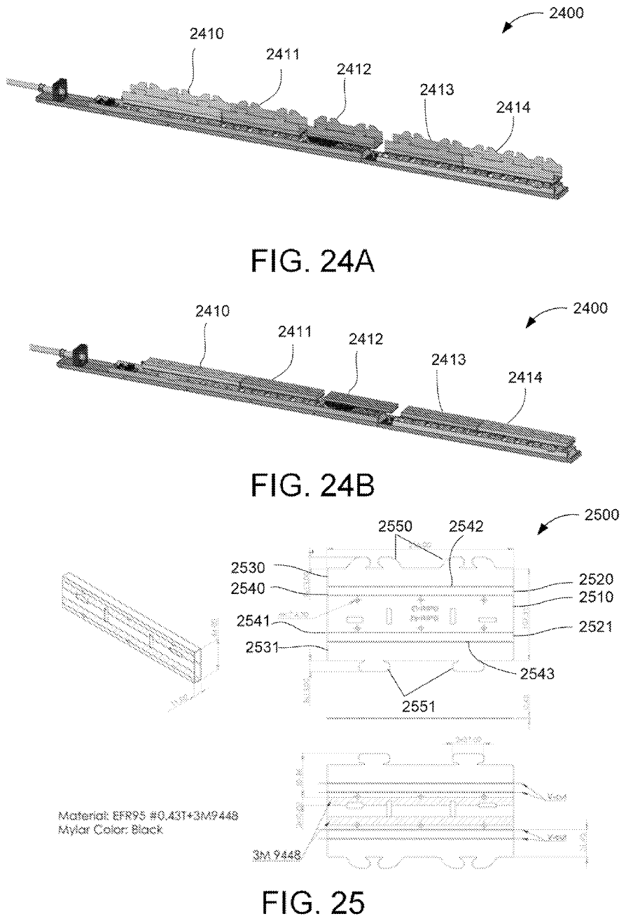

FIG. 23B shows another view of the enclosure system 2300 of FIG. 24A. As shown, a sub-assembly 2350 may be inserted into the front panel 2310. The sub-assembly 2350 may be any feasible sub-assembly including, but not limited to, a display assembly. The cover 2320 may be pivoted away from the front panel 2310 to allow the sub-assembly 2350 to be placed into position. For example, the cover 2320 may be pivoted on a hinge (not shown) captured by the bracket 2330.

FIG. 23C shows another view of the enclosure system 2300 of FIG. 23A. In this view, the cover 2320 has been rotated (pivoted) toward the front panel 2310 to hold the sub-assembly (not shown) in place. The cover 2320 may include one or more latching arms 2321 that may engage with holes 2311 in the front panel 2310. In this manner, the latching arms 2321 may lock the cover 2320 into a position that holds any feasible sub-assembly in place with respect to the front panel 2310.

FIG. 23D shows another view of the enclosure system 2300 of FIG. 23A. In this view, the sub-assembly 2350 (which may be a display) has been affixed and held in place with respect to the front panel 2310.

FIG. 24A shows an example foldable cable raceway system 2400. The foldable cable raceway system 2400 may include any number of individual foldable cable raceways. As shown, the foldable cable raceway system 2400 may include foldable cable raceways 2410, 2411, 2412, 2413, and 2414. Each foldable cable raceway 2410-2414 may be formed from a blank and can protect and enclose a variety of wires and/or cables. For example, the foldable cable raceways 2410-2414 may surround and add a layer of insulation to wires and/or cables. The foldable cable raceways 2410-2414 also guide a position (e.g., dress) various wires and/or cables. In some examples, the blank may be cut (for example die cut) to have particular features that enable a hollow raceway to be formed. As shown, the foldable cable raceways 2410-2414 may be folded to form a “U” channel to accept one or more cables. Furthermore, the foldable cable raceways 2410-2414 may be used in a variety of applications. Illustrated here, the foldable cable raceways 2410-2414 may be deployed within a power distribution unit (PDU). However, the foldable cable raceways 2410-2414 may also be used within a rack-mountable chassis.

FIG. 24B shows another view of the foldable cable raceway system 2400. In this view, foldable top sections of the cable raceways 2410-2414 have been folded over and locked together (interlocked) to from the cable raceway or channel. In some examples, any of the cable raceways 2410-2414 may include one or more holes that may be used to attach or fix the associated raceway to a structure, assembly, or object.

FIG. 25 shows various views of a blank 2500 for forming a foldable cable raceway. The blank 2500 may be formed from any feasible material. In some examples, the blank may be formed from Mylar, Kapton, polyurethane, Teflon, or the like. The material may in partially or wholly insulative. In some examples, the blank 2500 may be approximately 0.43 millimeters (mm) thick, although other thicknesses are possible.

The blank 2500 may include a number of sections. Some of the sections may be folded to form the cable raceway. For example, the blank 2500 may include a center panel 2510, a first foldable panel 2520, a second foldable panel 2521, a first top section 2530, and a second top section 2531. In some examples, the blank 2500 may be 218 mm long, although other lengths are possible.

The center panel 2510 may form a bottom or lower portion of the cable raceway. In some examples, the center panel 2510 may generally have a rectangular shape, however other shapes are possible.

Attached to opposing sides of the center panel 2510 may be the first foldable panel 2520 and the second foldable panel 2521. The first and second foldable panels 2520 and 2521 may form the sides of the raceway. In some examples, the first and second foldable panels may be approximately 11 mm in length. The corresponding cable channel for the blank 2500 may be approximately 11 mm tall. In some examples, the blank 2500 may include one or more pre-crease areas. For example, a first pre-crease 2540 may separate the first foldable panel 2520 from the center panel 2510 and a second pre-crease 2541 may separate the second foldable panel 2521 from the center panel 2510. A pre-crease may be any feature on the blank 2500 to assist a user in folding one or more sections of the blank 2500.

The first top section 2530 may be coupled to the first foldable panel 2520 via a third pre-crease 2542 and the second top section 2531 may be coupled to the second foldable panel 2521 by a fourth pre-crease 2543. The first top section 2530 and the second top section 2531 may include interlocking elements that enable the first top section 2530 and the second top section 2531 to removably couple to each other and thereby form a cable raceway to encircle or surround one or more cables. For example, the first top section 2530 may include one or more interlocking fingers 2550 and the second top section 2531 may include one or more interlocking tabs 2551. The interlocking tabs 2551 may be inserted between the interlocking fingers 2550 such that the interlocking fingers 2550 may capture or hold the interlocking tabs 2551. In some examples, the interlocking tabs 2551 may be approximately 13 mm high by 37 mm long. The corresponding interlocking fingers 2550 may be approximately 13 mm high.

It should be appreciated that all combinations of the foregoing concepts and additional concepts discussed in greater detail below (provided such concepts are not mutually inconsistent) are contemplated as being part of the inventive subject matter disclosed herein and may be used to achieve the benefits described herein.

When a feature or element is herein referred to as being “on” another feature or element, it can be directly on the other feature or element or intervening features and/or elements may also be present. In contrast, when a feature or element is referred to as being “directly on” another feature or element, there are no intervening features or elements present. It will also be understood that, when a feature or element is referred to as being “connected”, “attached” or “coupled” to another feature or element, it can be directly connected, attached or coupled to the other feature or element or intervening features or elements may be present. In contrast, when a feature or element is referred to as being “directly connected”, “directly attached” or “directly coupled” to another feature or element, there are no intervening features or elements present. Although described or shown with respect to one embodiment, the features and elements so described or shown can apply to other embodiments. It will also be appreciated by those of skill in the art that references to a structure or feature that is disposed “adjacent” another feature may have portions that overlap or underlie the adjacent feature.

Terminology used herein is for the purpose of describing particular embodiments only and is not intended to be limiting of the invention. For example, as used herein, the singular forms “a”, “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. As used herein, the term “and/or” includes any and all combinations of one or more of the associated listed items and may be abbreviated as “/”.

Spatially relative terms, such as “under”, “below”, “lower”, “over”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is inverted, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly. Similarly, the terms “upwardly”, “downwardly”, “vertical”, “horizontal” and the like are used herein for the purpose of explanation only unless specifically indicated otherwise.

Although the terms “first” and “second” may be used herein to describe various features/elements (including steps), these features/elements should not be limited by these terms, unless the context indicates otherwise. These terms may be used to distinguish one feature/element from another feature/element. Thus, a first feature/element discussed below could be termed a second feature/element, and similarly, a second feature/element discussed below could be termed a first feature/element without departing from the teachings of the present invention.

Throughout this specification and the claims which follow, unless the context requires otherwise, the word “comprise”, and variations such as “comprises” and “comprising” means various components can be co-jointly employed in the methods and articles (e.g., compositions and apparatuses including device and methods). For example, the term “comprising” will be understood to imply the inclusion of any stated elements or steps but not the exclusion of any other elements or steps.

In general, any of the apparatuses and methods described herein should be understood to be inclusive, but all or a sub-set of the components and/or steps may alternatively be exclusive, and may be expressed as “consisting of” or alternatively “consisting essentially of” the various components, steps, sub-components or sub-steps.

As used herein in the specification and claims, including as used in the examples and unless otherwise expressly specified, all numbers may be read as if prefaced by the word “about” or “approximately,” even if the term does not expressly appear. The phrase “about” or “approximately” may be used when describing magnitude and/or position to indicate that the value and/or position described is within a reasonable expected range of values and/or positions. For example, a numeric value may have a value that is +/−0.1% of the stated value (or range of values), +/−1% of the stated value (or range of values), +/−2% of the stated value (or range of values), +/−5% of the stated value (or range of values), +/−10% of the stated value (or range of values), etc. Any numerical values given herein should also be understood to include about or approximately that value, unless the context indicates otherwise. For example, if the value “10” is disclosed, then “about 10” is also disclosed. Any numerical range recited herein is intended to include all sub-ranges subsumed therein. It is also understood that when a value is disclosed that “less than or equal to” the value, “greater than or equal to the value” and possible ranges between values are also disclosed, as appropriately understood by the skilled artisan. For example, if the value “X” is disclosed the “less than or equal to X” as well as “greater than or equal to X” (e.g., where X is a numerical value) is also disclosed. It is also understood that the throughout the application, data is provided in a number of different formats, and that this data, represents endpoints and starting points, and ranges for any combination of the data points. For example, if a particular data point “10” and a particular data point “15” are disclosed, it is understood that greater than, greater than or equal to, less than, less than or equal to, and equal to 10 and 15 are considered disclosed as well as between 10 and 15. It is also understood that each unit between two particular units are also disclosed. For example, if 10 and 15 are disclosed, then 11, 12, 13, and 14 are also disclosed.

Although various illustrative embodiments are described above, any of a number of changes may be made to various embodiments without departing from the scope of the invention as described by the claims. For example, the order in which various described method steps are performed may often be changed in alternative embodiments, and in other alternative embodiments one or more method steps may be skipped altogether. Optional features of various device and system embodiments may be included in some embodiments and not in others. Therefore, the foregoing description is provided primarily for exemplary purposes and should not be interpreted to limit the scope of the invention as it is set forth in the claims.

The examples and illustrations included herein show, by way of illustration and not of limitation, specific embodiments in which the subject matter may be practiced. As mentioned, other embodiments may be utilized and derived there from, such that structural and logical substitutions and changes may be made without departing from the scope of this disclosure. Such embodiments of the inventive subject matter may be referred to herein individually or collectively by the term “invention” merely for convenience and without intending to voluntarily limit the scope of this application to any single invention or inventive concept, if more than one is, in fact, disclosed. Thus, although specific embodiments have been illustrated and described herein, any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

1. A hard-disk drive carrier, comprising:
a carrier frame configured to receive and affix a hard-disk drive thereto; and
a door frame coupled to the carrier frame, the door frame comprising:
a door pivotably coupled to the door frame; configured to rotate outward with respect to the door frame;
a first spring configured to apply a torsion force to bias the door inward with respect to the door frame;
a latch pawl configured to lock the hard-disk drive carrier to a chassis; and
a second spring configured to apply a compressive force to bias the latch pawl to protrude beyond the door frame and engage with the chassis,
wherein the door is further configured to contact and retract the latch pawl when the door is rotated outward.

2. The hard-disk drive carrier of claim 1, wherein the first spring is a torsion spring disposed about a pivot point, the first spring comprising a first arm coupled to the door and a second arm coupled to the door frame.

3. The hard-disk drive carrier of claim 1, wherein the second spring is a compression spring comprising a first end in contact with the door frame and a second end in contact with the latch pawl.

4. The hard-disk drive carrier of claim 1, wherein the latch pawl is configured to retract into the door frame when receiving a force from the door.

5. The hard-disk drive carrier of claim 1, wherein the door further comprises a tab configured to receive a user applied force to rotate the door outward with respect to the door frame.

6. The hard-disk drive carrier of claim 1, wherein the carrier frame further comprises a first light pipe configured to transmit light from a first end of the carrier frame to the door.

7. The hard-disk drive carrier of claim 6, wherein the door comprises a second light pipe configured to transmit light from the first light pipe to an exterior surface of the door.

8. A bezel assembly for a rack-mountable chassis, the bezel assembly comprising:
a bezel body;
a first latch handle and a second latch handle moveably coupled to the bezel body and configured to:
extend beyond first and second sides of the bezel body, respectively and engage with a rack-mountable chassis; and
retract inward from the first and the second sides of the bezel body and disengage from the rack-mountable chassis;
a first compression spring and a second compression spring configured to bias the first latch handle and the second latch handle, respectively, outward to extend beyond the first and the second sides of the bezel body;
a locking lever configured to:
lock and maintain an extension of at least one of the first latch handle and the second latch handle beyond the first and second sides of the bezel body when the locking lever is in a first position; and
allow at least one of the first latch handle and the second latch handle to retract inward from the first and second sides of the bezel body when the locking lever is in a second position, different than the first position; and
a torsion spring coupled to the locking lever and configured to bias the locking lever toward the second position,
wherein the bezel body is locked to the rack-mountable chassis when at least one of the first latch handle and the second latch handle is engaged with the rack-mountable chassis.

9. The bezel assembly of claim 8, wherein the first latch handle and the second latch handle are each configured to be moved inward from the first and second sides of the bezel body by a user to disengage the bezel body from the rack-mountable chassis.

10. The bezel assembly of claim 8, wherein the bezel body comprises a slot to receive a key configured to move the locking lever from the second position to the first position when the key is inserted into the slot.

11. The bezel assembly of claim 10, wherein the locking lever is configured to rotate in response to contact from the key.

12. The bezel assembly of claim 8, further comprising a release button movably coupled to at least one of the first latch handle and the second latch handle, wherein the release button is configured to block user force directed inward to at least one of the first latch handle and the second latch handle when the locking lever is in the second position, and wherein at least one of the first latch handle and the second latch handle is further configured to retract inward when force is directed toward the first latch handle and the second latch handle by the rack-mountable chassis when the locking lever is in the second position.

13. The bezel assembly of claim 8, further configured to prevent user access to hard-disk drive carriers removably coupled to the rack-mountable chassis when engaged to the rack-mountable chassis.

14. The bezel assembly of claim 8, further comprising a lock button configured to rotate the locking lever from the second position to the first position when the lock button comes in contact with the rack-mountable chassis.

15. The bezel assembly of claim 14, wherein the lock button is further configured to extend beyond a surface of the bezel assembly and retract inward with respect to the bezel assembly in response to contacting the rack-mountable chassis.

16. The bezel assembly of claim 14, wherein the locking lever is further configured to be rotated, by a key, to a third position different from the first and second positions, wherein the first latch handle and the second latch handle are further configured to retract inward from the first and the second sides of the bezel body and disengage from the rack-mountable chassis when the locking lever is in the third position.

17. The bezel assembly of claim 16, wherein the locking lever comprises a surface configured to contact the key and rotate the locking lever in response to pressure from the key.

18. The bezel assembly of claim 16, wherein at least one of the first latch handle and the second latch handle includes a slot configured to receive the key.

19. The bezel assembly of claim 8, wherein the locking lever is pivotably coupled to the bezel body.

20. The bezel assembly of claim 8, wherein at least one of the first latch handle and the second latch handle is further configured to include an opening to allow viewing of a display unit mounted to the rack-mountable chassis.

21.-33. (canceled)
